(19) United States
(12) Patent Application Publication
(10) Pub. No.: US 2008/0277656 A1
(43) Pub. Date: Nov. 13, 2008

(54) METHOD OF MANUFACTURING ZnO SEMICONDUCTOR LAYER FOR ELECTRONIC DEVICE AND THIN FILM TRANSISTOR INCLUDING THE ZnO SEMICONDUCTOR LAYER

(76) Inventors: Sang Hee PARK, Daejeon (KR); Chi Sun HWANG, Daejeon (KR); Hye Yong CHU, Daejeon (KR); Jeong Ik LEE, Gyeonggi (KR)

Correspondence Address: LADAS & PARRY LLP, 224 SOUTH MICHIGAN AVENUE, SUITE 1600, CHICAGO, IL, 60604, US

(21) Appl. No.: 11/970,737

(22) Filed: Jan. 8, 2008

(30) Foreign Application Priority Data
Jan. 9, 2007 (KR) 10-2007-0002525
May 29, 2007 (KR) 10-2007-0051792

(51) Int. Cl. H01L 21/20; H01L 29/786

(52) U.S. Cl. 257/43; 438/104; 257/E21.09; 257/E29.296

(57) ABSTRACT

Provided are a method of manufacturing a ZnO semiconductor layer for an electronic device, which can control the size of crystals of the ZnO semiconductor layer and the number of carriers using a surface chemical reaction between precursors, and a thin film transistor (TFT) including the ZnO semiconductor layer. The method includes: (a) loading a substrate into a chamber; (b) injecting a Zn precursor into the chamber to adsorb the Zn precursor on the substrate; (c) injecting an inert gas or N₂ gas into the chamber to remove the remaining Zn precursor; (d) injecting an oxygen precursor into the chamber to cause a reaction between the oxygen precursor and the Zn precursor adsorbed on the substrate to form the ZnO semiconductor layer; (e) injecting the N₂ gas or inert gas into the chamber to remove the remaining oxygen precursor; (f) repeating steps (a) through (e); (g) repeatedly processing the surface treatment of the ZnO semiconductor layer using O₂ plasma or O₃; (h) injecting the N₂ gas or inert gas into the chamber to remove the remaining oxygen and Zn precursors; and (i) repeating steps (a) through (h) to control the thickness of the ZnO semiconductor layer. In this method, a transparent TFT is formed using a transparent substrate to enable manufacture of a transparent display device, and a flexible display device can be manufactured using a flexible substrate. Also, the crystallinity of the ZnO semiconductor layer can be increased to improve the mobility of a TFT, and the number of carriers can be controlled to reduce a leakage current. Therefore, a ZnO semiconductor having excellent characteristics can be manufactured.

### CROSS-REFERENCE TO RELATED APPLICATION

This application claims priority to and the benefit of Korean Patent Application Nos. 2007-2525, filed Jan. 9, 2007 and 2007-51792, filed May 29, 2007, the disclosures of which are incorporated herein by reference in their entirety.

### BACKGROUND

1. Field of the Invention

The present invention relates to a method of manufacturing a Zinc Oxide (ZnO) semiconductor layer for an electronic device and, more particularly, to a method of manufacturing a ZnO semiconductor layer for an electronic device by causing a surface chemical reaction between an oxygen precursor and a Zn precursor using an Atomic Layer Deposition (ALD) technique, and a thin film transistor (TFT) including the ZnO semiconductor layer.

The present invention has been produced from the work supported by the IT R&D program of MIC (Ministry of Information and Communication)/IITA (Institute for Information Technology Advancement) [2006-S-079-01, Smart window with transparent electronic devices] in Korea.

2. Discussion of Related Art

In modern times, the demand for electronic devices that can be used any time any place is widespread. Among the electronic devices, thin film transistors (TFTs) are being widely used for not only semiconductor devices but also display devices, radio-frequency identification (RFID), and sensors. The TFTs may be classified into amorphous silicon (a-Si) transistors and polysilicon (poly-Si) transistors. Also, organic TFTs using organic semiconductors have lately been developed.

In recent years, development of TFTs using II-VI group transparent semiconductors having a wide bandgap has attracted much attention. Among currently known transparent TFTs, a “transistor using InGaO₃(ZnO)₅ as semiconductor”, which was disclosed in Science Magazine (vol. 300, p. 1269) by the Hosono Group in 2003, has the highest mobility. In addition, a “transistor using ZnO as semiconductor” has been discussed by Wager et al. in App. Phys. Lett., (vol. 82, p. 733) in 2003, and a “transparent transistor formed of semiconductors, such as ZnO, MgZnO, or CadZnO, and having an inorganic double insulating structure” has been proposed in U.S. Pat. No. 6,563,174 B2 by M. Kawasaki et al.

Most transparent semiconductors used for currently published transparent TFTs are deposited using a Pulsed Laser Deposition (PLD) technique, a sputtering technique, or an ion-beam sputtering technique. Also, since deposited transparent semiconductors are subject to a high-temperature thermal treatment process, scaling up the transparent semiconductors is difficult and the transparent TFTs are inferior in terms of performance to a-Si TFTs. Furthermore, because manufacturing the transparent TFTs is costly, the transparent TFTs are inadequate for ubiquitous environments requiring low-priced TFTs.

In order to overcome the foregoing drawbacks, research has been conducted on manufacturing organic TFTs (OTFTs) based on plastic substrates using organic semiconductors. However, since the OTFTs have poorer performance than conventional TFTs, applying the OTFTs to typical electronic devices is not easy. Also, organic semiconductors are susceptible to environmental factors such as oxygen, water, and heat and prone to deterioration, thereby restricting the lifetime of the organic semiconductor. An inorganic TFT based on a plastic substrate using an inorganic semiconductor may deteriorate due to a low-temperature process, so that it is impossible to obtain inorganic TFTs having good characteristics.

In order to overcome the foregoing technical limitations, the present applicant has proposed a “technique for manufacturing a transistor including a ZnO thin layer formed using an Atomic Layer Deposition (ALD) process” in SID 06 (proceeding). When manufacturing a TFT including a transparent substrate, such as a glass substrate or a plastic substrate, and a transparent oxide electrode using the transistor technique using the ALD process, the entire transistor is made transparent. Thus, when the manufactured TFT is applied to a Liquid Crystal Display (LCD) device, the aperture ratio of pixels and the luminance of the LCD can be increased. Also, when manufacturing a TFT including a semiconductor layer formed on a plastic substrate using the foregoing technique, because the TFT has better characteristics than an OTFT or an amorphous TFT and hardly deteriorates in an external environment, a flexible transistor array can be manufactured. In particular, when an Organic Light Emitting Diode (OLED) display device is fabricated on the flexible transistor array manufactured using the above-described technique, a flexible transparent display can be embodied. In addition, a TFT manufactured using the above-described technique can be applied not only to electronic devices, such as RFIDs, but also to sensors.

However, when a semiconductor layer is formed using an ALD process, it is difficult to sufficiently improve the mobility of a TFT due to a small crystal size of the semiconductor layer. Here, the crystal size of the semiconductor layer is small due to the fact that a crystal formed at an interface between an insulating layer and the semiconductor layer has a very small size and the semiconductor layer is not deposited to an appropriate thickness in order to lessen a deposition time of the semiconductor layer in consideration of mass production of the TFTs.

### SUMMARY OF THE INVENTION

The present invention is directed to a method of manufacturing a ZnO semiconductor layer for an electronic device in which much larger crystals can be grown in a thin semiconductor layer to improve mobility, and a thin film transistor (TFT) including the ZnO semiconductor layer.

Also, the present invention is directed to a method of manufacturing a ZnO semiconductor layer for an electronic device and a TFT including the ZnO semiconductor layer, which inhibit an increase in leakage current caused by a rise in the number of carriers accompanying growth of larger crystals using an Atomic Layer Deposition (ALD) technique, so that an on/off ratio of the TFT can be enhanced.

One aspect of the present invention provides a method of manufacturing a ZnO semiconductor layer for an electronic device. The method includes the steps of: (a) loading a substrate into a chamber; (b) injecting a Zn precursor into the chamber to adsorb the Zn precursor on the substrate; (c) injecting an inert gas or N₂ gas into the chamber to remove the remaining Zn precursor; (d) injecting an oxygen precursor into the chamber to cause a reaction between the oxygen precursor and the Zn precursor adsorbed on the substrate to form the ZnO semiconductor layer; (e) injecting the N₂ gas or inert gas into the chamber to remove the remaining oxygen precursor; (f) repeating steps (a) through (e); (g) repeatedly processing the surface treatment of the ZnO semiconductor layer using oxygen plasma or O₃; (h) injecting the N₂ gas or inert gas into the chamber to remove the remaining oxygen and Zn precursors; and (i) repeating steps (a) through (h) to control the thickness of the ZnO semiconductor layer.

The ZnO semiconductor layer may be formed to a thickness of about 8 to 100 nm. Step (f) may be repeated three to twenty times, and step (g) may be repeated one to ten times.

The Zn precursor injected into the chamber may include diethyl zinc or dimethyl zinc, and the oxygen precursor injected into the chamber may include water (H₂O) or H₂O plasma. The substrate may be formed of glass, metal foil, plastic, or silicon. Steps (a) through (h) may be performed using an Atomic Layer Deposition (ALD) technique. The ALD technique may include a traveling wave reactor type ALD technique, a remote plasma ALD technique, or a direct plasma ALD technique.

Another aspect of the present invention provides a TFT including a ZnO semiconductor layer manufactured using the above-described method. The TFT includes: a gate electrode disposed on a substrate; the ZnO semiconductor layer disposed on or under the gate electrode; source and drain electrodes electrically connected to the ZnO semiconductor layer; and an insulating layer interposed between the gate electrode and the ZnO semiconductor layer.

The insulating layer may include at least one layer, which is formed of an inorganic material, an organic material, or an organic-inorganic hybrid material. Each of the gate electrode and the source and drain electrodes may include at least one layer, which is formed of at least one of indium tin oxide (ITO), indium zinc oxide (IZO), ZnO:Al, ZnO:Ga, Ag, Au, Al, Al/Nd, Cr, Al/Cr/Al, Ni, and Ti.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view of a thin film transistor (TFT) including a semiconductor layer manufactured according to an exemplary embodiment of the present invention;

FIG. 2 is a block diagram illustrating a method of manufacturing the semiconductor layer shown in FIG. 1;

FIGS. 3A through 3D are cross-sectional views of a TFT including the semiconductor layer manufactured according to the method shown in FIG. 2; and

FIGS. 4A through 4D are scanning electron microscope (SEM) photographs of ZnO semiconductor layers manufactured using a method according to the present invention.

### DETAILED DESCRIPTION OF EMBODIMENTS

The present invention will now be described more fully hereinafter with reference to the accompanying drawings, in which exemplary embodiments of the invention are shown.

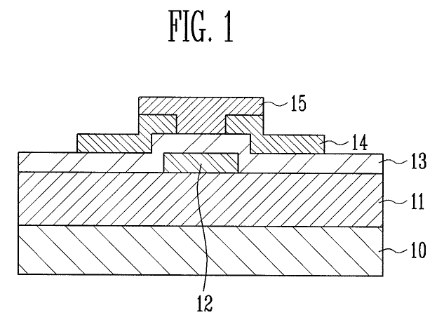

FIG. 1 is a cross-sectional view of a thin film transistor (TFT) including a semiconductor layer manufactured according to an exemplary embodiment of the present invention.

Referring to FIG. 1, a TFT 1 includes a substrate 10, an insulating layer 11 disposed on the substrate 10, a gate electrode 12 disposed on the insulating layer 11, a gate insulating layer 13 disposed on the gate electrode 12, source and drain electrodes 14 disposed on the gate insulating layer 13, and a semiconductor layer 15 disposed on the gate insulating layer 13 to contact the source and drain electrodes 14.

The substrate 10 may be formed of various materials, such as glass, silicon, metal foil such as stainless steel (SUS), and plastic. When manufacturing a TFT using a transparent substrate, a transparent display device can be embodied, and when manufacturing a TFT using a flexible substrate, a display device having a good flexural characteristic can be embodied.

The insulating layer 11 may be formed of an inorganic material or an organic material. Specifically, the insulating layer 11 may be one selected from the group consisting of a single inorganic insulating layer, an inorganic insulating layer having a multi layered structure, a single organic insulating layer, an organic insulating layer having a multi layered structure, and an organic-inorganic hybrid insulating layer. For example, the insulating layer 11 may be formed of an inorganic material selected from the group consisting of SiNₓ, AlON, TiO₂ AlOₓ, TaOₓ, HfOₓ, SiO_{N}, and SiOₓ.

The gate electrode 12 may be formed of transparent oxide, such as indium tin oxide (ITO), indium zinc oxide (IZO), ZnO:Al, or ZnO:Ga, or a low-resistance metal, such as Ag, Au, Al, Al/Nd, Cr, Al/Cr/Al, Ni, or Ti. The gate electrode 12 may be formed by stacking at least one transparent oxide or metal layer or stacking a transparent oxide layer and a metal layer.

Like the insulating layer 11, the gate insulating layer 13 disposed on the gate electrode 12 may be one selected from the group consisting of a single inorganic insulating layer, an inorganic insulating layer having a multi layered structure, a single organic insulating layer, an organic insulating layer having a multi layered structure, and an organic-inorganic hybrid insulating layer. In this case, however, the gate insulating layer 13 may be formed of a metal having an etch selectivity with respect to the gate electrode 12 so as to enable the etching of the gate insulating layer 13. When the gate insulating layer 13 is an organic-inorganic hybrid insulating layer, an oxide/inorganic insulating layer may have an interface with the semiconductor layer 15. In this case, a portion contacting the semiconductor layer 15 that will be formed subsequently may have about the same work function as the semiconductor layer 15. When each of the insulating layer 11 and the gate insulating layer 13 has an organic-inorganic hybrid structure, stress caused by warping of the structure can be removed during manufacture of a flexible TFT array, and the insulating layer 11 and a plastic substrate can be easily used because the gate insulating layer 13 can be formed at low temperatures.

Like the gate electrode 12, the source and drain electrodes 14 disposed on the gate insulating layer 13 may be formed of transparent oxide, such as ITO, IZO, ZnO:Al, or ZnO:Ga, or a low-resistance metal, such as Ag, Au, Al, Al/Nd, Cr, Al/Cr/Al, Ni, or Ti. The transparent oxide has about the same work function as a ZnO semiconductor layer 15 provided using an Atomic Layer Deposition (ALD) technique.

The semiconductor layer 15 is disposed on the source and drain electrodes 14 and the gate insulating layer 13. The semiconductor layer 15 is formed using an ALD technique, specifically, by causing a surface chemical reaction between precursors. More specifically, the semiconductor layer 15 is a ZnO semiconductor layer formed by causing a surface chemical reaction between an oxygen precursor and a Zn precursor.

In the present invention, the ALD technique includes alternating a process of chemisorbing molecules on the surface of a substrate using a chemical combination and a process of causing substitution, combustion, and protonation reactions between an adsorbed precursor and a subsequent precursor using a surface chemical reaction. That is, the ALD technique includes repeating a cycle including the chemisorption reaction and the substitution reaction, thereby enabling hyperfine layer-by-layer deposition and minimizing the deposited thickness of an oxide. ALD techniques used for forming a semiconductor layer may be largely classified into a traveling wave reactor type ALD technique and a plasma-enhanced ALD technique. Also, the plasma-enhanced ALD technique may be divided into a remote plasma ALD (or a downstream plasma ALD) technique and a direct plasma ALD technique according to the type of a plasma generator. Since the present invention is not affected by the type of ALD technique, any one of the foregoing ALD techniques can be employed.

Hereinafter, a process of manufacturing a semiconductor layer using an ALD technique will be described in detail with reference to FIG. 2.

FIG. 2 is a block diagram illustrating a method of manufacturing the semiconductor layer shown in FIG. 1.

Referring to FIG. 2, in order to form a ZnO semiconductor layer 15, initially, a substrate 10 including an insulating layer 11, a gate electrode 12, a gate insulating layer 13, and source and drain electrodes 14 is loaded in a chamber (not shown) of an ALD apparatus in step S11. The chamber is maintained at a temperature of 100 to 250° C.

After loading the substrate 10 into the chamber, a Zn precursor is injected into the chamber in step S12. In this case, only the Zn precursor is injected in a vapor state into the chamber or the Zn precursor is injected along with a carrier gas, such as N₂ or Ar gas, into the chamber. When the Zn precursor is injected, a Zn precursor reactant is adsorbed on the surface of the substrate 10. In the current embodiment, diethyl zinc or dimethyl zinc may be used as the Zn precursor.

In step S13, a gas valve is opened and N₂ gas or an inert gas is injected into the chamber. By injecting the N₂ gas or the inert gas into the chamber, unadsorbed molecules of the Zn precursor reactant are completely removed. Thereafter, an oxygen precursor is injected into the chamber in step S14. The oxygen precursor may be water (H₂O), ozone (O₃), oxygen (O₂), O₂ plasma, or H₂O plasma. In the current embodiment, the ZnO semiconductor layer 15 is formed using water as the oxygen precursor so that the size of ZnO crystals can be increased. In this case, H₂O gas is injected into the chamber. In step S15, N₂ gas or an inert gas is injected into the chamber, thereby removing volatile products containing the remaining H₂O molecules, which are obtained by a reaction between the Zn precursor and the H₂O.

After steps S12 to S15 are performed, the process returns to step S12 and repeats steps S12 to S15. In this case, steps S12 to S15 may be repeated three to twenty times. A deposition time taken to perform steps S12 to S15 once may depend on the injected amounts of precursors, which depend on the size of the substrate 10. When the ZnO semiconductor layer 15 is formed using water as the oxygen precursor as in the present embodiment, the ZnO semiconductor layer 15 may be formed to a thickness of about 8 to 100 nm. When the thickness of the ZnO semiconductor layer 15 exceeds 100 nm, formation of the ZnO semiconductor layer 15 takes much time and the number of carriers in the ZnO semiconductor layer 15 increases, thus degrading the characteristics of a TFT.

After steps S12 to S15 are repeated in a predetermined number of times, the surface of the ZnO semiconductor layer 15 is processed using O₂ plasma or O₃ in step S16. The surface treatment processing of the ZnO semiconductor layer 15 using the O₂ plasma or O₃ a may be performed one to ten times. In this case, the O₂ plasma or O₃ is exposed to the surface of the ZnO semiconductor layer 15 to remove oxygen vacancies or other contaminants such as carbon atoms. As a result, the number of carriers in the ZnO semiconductor layer 15 can be controlled, thereby enabling manufacture of the ZnO semiconductor layer 15 having appropriate characteristics for the TFT. When the O₂ plasma is used to remove defects of the ZnO semiconductor layer 15, a direct plasma method or a remote plasma method may be employed. In the direct plasma method, plasma is immediately generated between a substrate and an electrode to which a precursor is injected in a chamber. In the remote plasma method, plasma is generated outside a chamber and injected into the chamber.

After removing the defects of the ZnO semiconductor layer 15, N₂ gas or an inert gas is injected into the chamber to remove impurities from the substrate 10 in step S17.

Meanwhile, steps S12 to S17 are repeated several times until the ZnO semiconductor layer 16 is grown to a desired thickness. In this case, the entire cycle including the process of growing the ZnO semiconductor layer 15 and the process of removing the defects of the ZnO semiconductor layer 15 is repeated, so that the characteristics of the ZnO semiconductor layer 15 can be improved as compared with when the entire ZnO semiconductor layer is formed all at once.

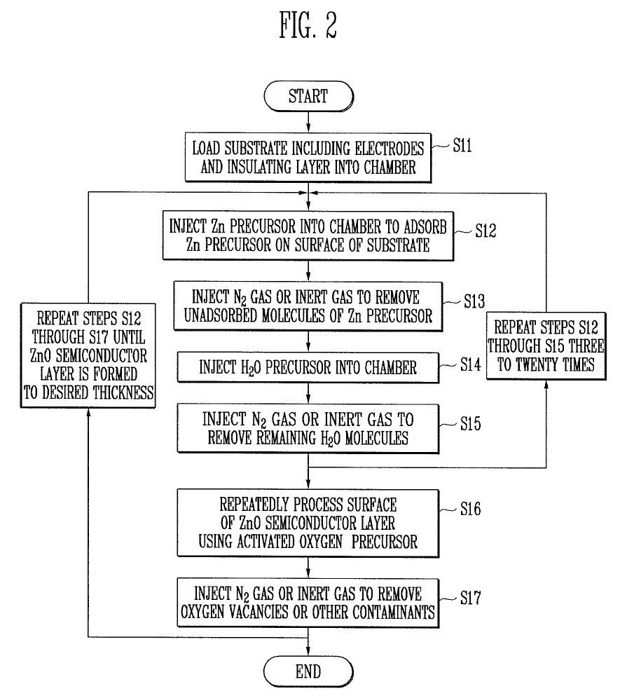

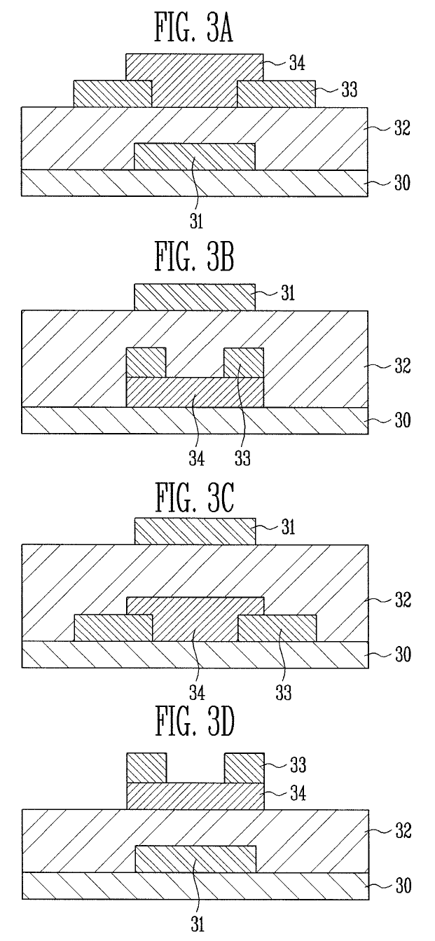

FIGS. 3A through 3D are cross-sectional views of a TFT including the semiconductor layer manufactured according to the method shown in FIG. 2.

The ZnO semiconductor layer manufactured according to the method described with reference to FIG. 2 can be used for various TFTs. In general, TFTs may be classified into a staggered type TFT and a planar type TFT according to an order in which a semiconductor layer, a gate insulating layer, a gate electrode, and source and drain electrodes are formed. The staggered type TFT includes the semiconductor layer interposed between the gate electrode and the source and drain electrodes. The coplanar type TFT includes the gate electrode and the source and drain electrodes, all of which are formed on one side of the semiconductor layer. Alternatively, TFTs may be categorized into a top-gate TFT and a bottom-gate TFT according to the position of a gate electrode relative to source and drain electrodes over a substrate.

FIG. 3A shows a bottom-gate inverted planar type TFT in which a gate electrode 31 and source and drain electrodes 33 are formed under a ZnO semiconductor layer 34. Referring to FIG. 3A, the gate electrode 31, a gate insulating layer 32, the source and drain electrodes 33, and a ZnO semiconductor layer 34 are formed on the substrate 30. In order to manufacture the inverted planar type TFT, a thin metal layer is deposited on the substrate 30. The thin metal layer is patterned using photolithographic and etching process to form the gate electrode 31 in a desired shape. The gate insulating layer 32 is deposited on the gate electrode 31. The gate insulating layer 32 of the TFT is formed using an ALD process or a plasma-enhanced chemical vapor deposition (PECVD) process. A contact hole (not shown) is formed in the gate insulating layer 32, and a thin metal layer for source and drain electrodes is deposited. The thin metal layer for the source and drain electrodes is patterned using photolithographic and etching processes, thereby forming the source and drain electrodes 33. The ZnO semiconductor layer 34 is deposited on the substrate 30 having the source and drain electrodes 33 at a temperature of about 150° C. in the same manner as described with reference to FIG. 2, and patterned.

FIG. 3B shows a top-gate planar type TFT in which source and drain electrodes 33, a gate insulating layer 32, and a gate electrode 31 are formed on a semiconductor layer 34. FIG. 3C shows a top-gate staggered type TFT in which source and drain electrodes 33 are formed under a semiconductor layer 34 and a gate electrode 31 is formed on the semiconductor layer 34. Also, FIG. 3D shows a bottom-gate inverted staggered type TFT in which a gate electrode 31 is formed under a semiconductor layer 34 and source and drain electrodes 33 are formed on the semiconductor layer 34. As exemplarily illustrated in FIGS. 3A through 3D, the ZnO semiconductor layer manufactured according to the method described with reference to FIG. 2 can be applied to various kinds of TFTs.

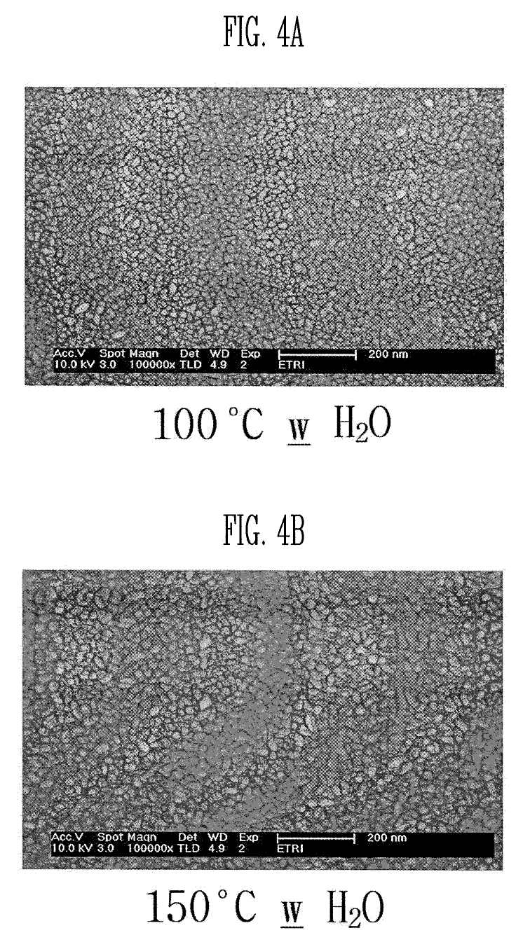

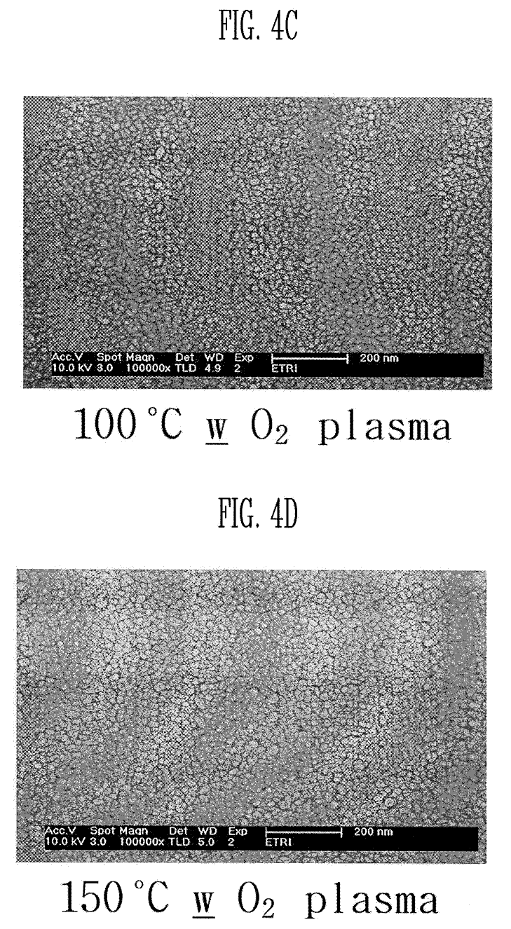

FIGS. 4A through 4D are scanning electron microscope (SEM) photographs of ZnO semiconductor layers manufactured using a method according to the present invention.

The present invention is characterized by increasing the size of crystals of a ZnO semiconductor layer using H₂O as an oxygen precursor and a Zn precursor and decreasing the number of carriers in the ZnO semiconductor layer using O₂ plasma or O₃. FIGS. 4A and 4B show the sizes of ZnO semiconductor layers grown using H₂O precursors, and FIGS. 4C and 4D show the sizes of ZnO semiconductor layers grown using O₂ plasma. The photographs shown in FIGS. 4A and 4C were taken when the ZnO semiconductor layers were grown using H₂O precursors at a temperature of about 100° C., and the photographs shown in FIGS. 4B and 4D were taken when the ZnO semiconductor layers were grown using H₂O precursors at a temperature of 150° C. Referring to FIGS. 4A through 4D, it can be seen that as a deposition temperature increases, the size of crystals of the ZnO semiconductor layer increases.

Meanwhile, when the deposition process is performed using the H₂O precursor as shown in FIGS. 4A and 4B, the ZnO semiconductor layer has a larger crystal size than when the deposition process is performed using the O₂ plasma as shown in FIGS. 4C and 4D. However, although the crystal size generally increases in proportion to the deposition temperature, when the ZnO semiconductor layer is deposited using H₂O and diethyl zinc at a temperature of 150° C. or higher, the number of carriers excessively increases in the Zn semiconductor layer due to oxygen vacancies. Furthermore, when the ZnO semiconductor layer is deposited using O₂ plasma, it is possible to control the number of carriers, but it can be observed that crystals in the Zn semiconductor layer have a smaller size than when the ZnO semiconductor layer is deposited using an H₂O precursor.

Therefore, according to the present invention, a ZnO semiconductor layer is grown using a Zn precursor and H₂O to increase the size of crystals, and the surface of the ZnO semiconductor layer is processed using O₂ plasma or O₃ to reduce the number of carriers. As a result, a TFT including the ZnO semiconductor layer manufactured according to the present invention has improved mobility and on/off ratio, as compared with conventional TFTs manufactured using an ALD technique. Specifically, the TFT including the ZnO semiconductor layer according to the present invention has a mobility of 10 cm²/V.sec and an on/off ratio of 10⁷, while a conventional TFT manufactured using an ALD technique has a mobility of 0.5 to 2.0 cm²/V.sec. Also, when a staggered type TFT is manufactured using the ZnO semiconductor layer according to the present invention, the crystallinity of a channel is excellent as to increase the mobility of the TFT, and the influence of resistance of the ZnO semiconductor layer can be minimized due to a small thickness thereof.

According to the present invention as described above, formation of a ZnO semiconductor layer using an ALD technique can be performed at a temperature of 100 to 250° C., so that a TFT including the ZnO semiconductor layer can be manufactured on a large-area glass substrate or plastic substrate. In this case, since a high-temperature post-processing process may not be performed, a ZnO semiconductor layer with good characteristics can be obtained at a low temperature. The obtained ZnO semiconductor layer can be used for TFT arrays having various structures, and thus it can be applied to a variety of devices, such as transparent display devices, flexible display devices, RFIDs, and sensors.

Furthermore, according to the present invention, the size of crystals of the ZnO semiconductor layer can be increased to improve the mobility of a TFT, and a leakage current can be reduced by controlling the number of carriers. Therefore, a transparent ZnO semiconductor layer with excellent characteristics can be manufactured.

In the drawings and specification, there have been disclosed typical preferred embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A method of manufacturing a ZnO semiconductor layer for an electronic device, the method comprising the steps of:
(a) loading a substrate into a chamber;
(b) injecting a Zn precursor into the chamber to adsorb the Zn precursor on the substrate;
(c) injecting an inert gas or N₂ gas into the chamber to remove the remaining Zn precursor;
(d) injecting an oxygen precursor into the chamber to cause a reaction between the oxygen precursor and the Zn precursor adsorbed on the substrate to form the ZnO semiconductor layer;
(e) injecting the N₂ gas or inert gas into the chamber to remove the remaining oxygen precursor;
(f) repeating steps (a) through (e);
(g) repeatedly processing the surface treatment of the ZnO semiconductor layer using O₂ plasma or O₃;
(h) injecting the N₂ gas or inert gas into the chamber to remove the remaining oxygen and Zn precursors; and
(i) repeating steps (a) through (h) to control the thickness of the ZnO semiconductor layer.

2. The method according to claim 1, wherein the ZnO semiconductor layer is formed to a thickness of about 8 to 100 nm.

3. The method according to claim 1, wherein step (f) is repeated three to twenty times.

4. The method according to claim 1, wherein step (g) is repeated one to ten times.

5. The method according to claim 1, wherein the Zn precursor injected into the chamber comprises diethyl zinc or dimethyl zinc.

6. The method according to claim 1, wherein the oxygen precursor injected into the chamber comprises water (H₂O) or H₂O plasma.

7. The method according to claim 1, wherein the substrate is formed of one selected from the group consisting of glass, metal foil, plastic, and silicon.

8. The method according to claim 1, wherein steps (a) through (h) are performed using an Atomic Layer Deposition (ALD) technique.

9. The method according to claim 8, wherein the ALD technique is one selected from the group consisting of a traveling wave reactor type ALD technique, a remote plasma ALD technique, and a direct plasma ALD technique.

10. A thin film transistor (TFT) comprising a ZnO semiconductor layer manufactured using the method according to any one of claims 1 through 9, the TFT comprising:
a gate electrode disposed on a substrate;
the ZnO semiconductor layer disposed on or under the gate electrode;
source and drain electrodes electrically connected to the ZnO semiconductor layer; and
an insulating layer interposed between the gate electrode and the ZnO semiconductor layer.

11. The TFT according to claim 10, wherein the insulating layer comprises at least one layer, which is formed of one selected from the group consisting of an inorganic material, an organic material, and an organic-inorganic hybrid material.

12. The TFT according to claim 10, wherein each of the gate electrode and the source and drain electrodes comprises at least one layer, which is formed of at least one selected from the group consisting of indium tin oxide (ITO), indium zinc oxide (IZO), ZnO:Al, ZnO:Ga, Ag, Au, Al, Al/Nd, Cr, Al/Cr/Al, Ni, and Ti.
